(19) United States
(12) Patent Application Publication
(10) Pub. No.: US 2024/0385509 A1
(43) Pub. Date: Nov. 21, 2024

(54) LITHOGRAPHY SYSTEM AND METHODS

(71) Applicant: Taiwan Semiconductor Manufacturing Co., Ltd., Hsinchu (TW)

(72) Inventors: Chi YANG, Hsinchu (TW); Yao-Tang LIN, Hsinchu (TW); Zi-Wen CHEN, Hsinchu (TW); Jian-Yuan SU, Hsinchu (TW)

(21) Appl. No.: 18/320,566

(22) Filed: May 19, 2023

(51) Int. Cl. G03F 1/64; G03F 7/20; G03F 9/00

(52) U.S. Cl. CPC G03F 1/64; G03F 7/70983; G03F 9/7026

(57) ABSTRACT

A method includes: determining whether a first pellicle is to be inspected for inner particles; and in response to the first pellicle being to be inspected: forming a mask layer on a substrate; forming a defocused light path by shifting a mask assembly; exposing the mask layer by defocused light having a focal plane separated from the first pellicle by a distance; taking an image of the substrate; determining whether a threshold value is exceeded by analyzing the image; in response to the threshold value being exceeded, replacing the first pellicle with a second pellicle; and in response to the threshold value not being exceeded, processing production wafers using the first pellicle.

### BACKGROUND

The semiconductor integrated circuit (IC) industry has experienced exponential growth. Technological advances in IC materials and design have produced generations of ICs where each generation has smaller and more complex circuits than the previous generation. In the course of IC evolution, functional density (i.e., the number of interconnected devices per chip area) has generally increased while geometry size (i.e., the smallest component (or line) that can be created using a fabrication process) has decreased. This scaling down process generally provides benefits by increasing production efficiency and lowering associated costs. Such scaling down has also increased the complexity of processing and manufacturing ICs.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A and 1B are views of portions of a lithography scanner according to embodiments of the present disclosure.

FIGS. 2A-2C are views of various embodiments of a mask assembly of the lithography scanner according to various aspects of the present disclosure.

FIGS. 3A-3G are views illustrating use of a pellicle in accordance with various embodiments.

FIGS. 4A-4D are views illustrating detecting a particle on a pellicle in accordance with various embodiments.

FIG. 5 is a view illustrating a method of fabricating a device according to various aspects of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Terms such as “about,” “roughly,” “substantially,” and the like may be used herein for ease of description. A person having ordinary skill in the art will be able to understand and derive meanings for such terms.

The present disclosure is generally related to lithography equipment for fabricating semiconductor devices, and more particularly to methods of inspecting a pellicle that is part of a mask assembly. Dimension scaling (down) is increasingly difficult in advanced technology nodes. Lithography techniques employ ever shorter exposure wavelengths, including deep ultraviolet (DUV; about 193-248 nanometers), extreme ultraviolet (EUV; about 10-100 nanometers; particularly 13.5 nanometers), and X-ray (about 0.01-10 nanometers) to ensure accurate patterning at the scaled-down dimensions. In an EUV scanner, EUV light is generated by a light source, and reflected toward a wafer by multiple mirrors and a reflective mask. Only a fraction of the EUV light reaches the wafer, such that increasing intensity of EUV light generated by the light source is a topic of much interest.

In EUV lithography, patterns of a mask or reticle are reflected toward a wafer to expose and print the patterns to the wafer. Particles from an EUV scanner chamber, which is a vacuum environment due to EUV absorption, can transport freely onto a pattern-carrying surface of the reticle, forming reticle defects and leading to pattern failure in all exposure fields. Mounting a pellicle, which may be a nanometer-scale thickness thin film that is transparent to EUV wavelengths, at a selected distance from the reticle can prevent reticle defects formed by particles released from the tool. The distance is selected to be far enough away from the reticle focus plane so that no pattern failure occurs due to any particle on the outer surface of the pellicle (e.g., the surface of the pellicle facing away from the reticle), as long as the particle size and EUV transparency are small and clear, respectively.

The pellicle is beneficial to prevent some particles from settling on the reticle. However, the pattern failure may still occurs due to particles at an inner region of the pellicle, which are referred to as “inner on-pellicle defects” (IOPDs). IOPDs can be formed in various ways. For example, the IOPD may be formed during a thin film process that forms the pellicle, may be induced during mounting of the pellicle to the reticle, or due to bond breaking of pellicle elements after EUV exposure. The IOPD may also be formed during processing of semiconductor wafers, as some particles in the chamber may ingress through holes in a frame to which the pellicle is attached that are used for pressure balancing. Once the IOPD detaches from the inner surface of the pellicle, the IOPD can induce pattern failure after settling on the reticle surface.

Prior to pellicle mounting, an inspection process may be performed for pellicle qualification. However, particle size resolution may only be about 300 nanometers (nm). Particles smaller than 300 nm may not be identified in the inspection process. After pellicle mounting, a reticle inspection tool may not be used, because the pellicle under tension is easily ruptured by fluctuation and external vibration. One effective method to identify IOPD after mounting is performing wafer exposure and checking whether pattern failure occurs. However, yield is reduced by the number of wafers sent for wafer defect inspection. The wafer defect inspection tool may also be heavily taxed by IOPD detection, and have reduced availability for other inspection tasks. Once the IOPD attaches on the pattern surface, an increased batch size results in an increased reduction in yield.

In embodiments of this disclosure, a method that identifies IOPD by defocused EUV light is described. The method may be performed by defocusing the reticle until the pellicle lies on the focus plane or by defocusing the EUV light itself. Then, wafer exposure, an EUV camera, an EUV wavefront camera (defocus wavefront error) and the like may be used to image the IOPDs. An algorithm that calculates dynamics of defocus image aberration may be used when using the defocus wavefront measurement. The method of the embodiments may trace the evolution of IOPDs, count the number of IOPDs, and set up a threshold value for triggering pellicle re-mounting proactively without impact to fabrication of production wafers. The wafer yield can thereby be improved.

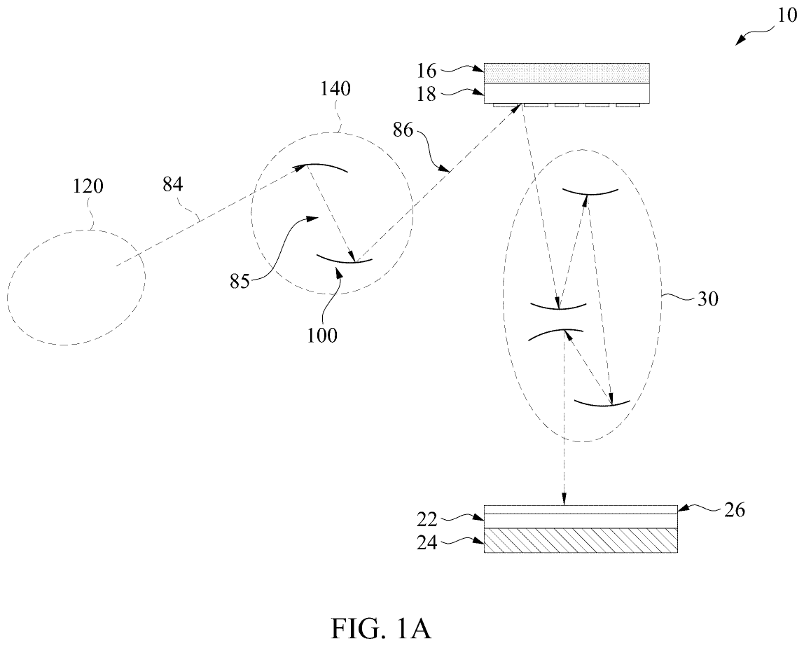

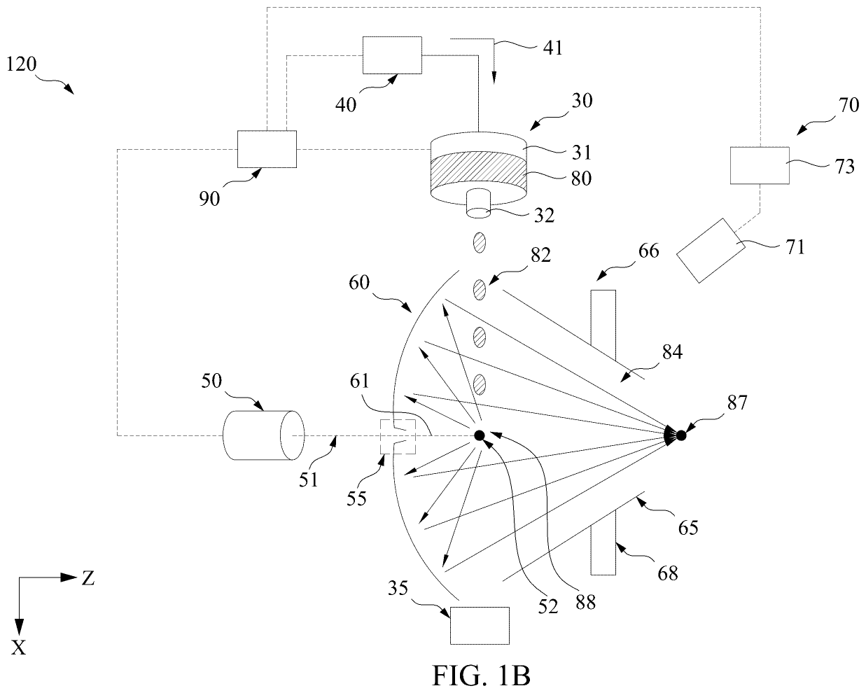

FIG. 1A is a schematic and diagrammatic view of a lithography exposure system 10, in accordance with some embodiments. In some embodiments, the lithography exposure system 10 is an extreme ultraviolet (EUV) lithography system designed to expose a resist layer by EUV radiation, and may also be referred to as the EUV system 10. The EUV system 10 may also be referred to as an EUV scanner or lithography scanner. The lithography exposure system 10 includes a light source 120, an illuminator 140, a mask stage 16, a projection optics module (or projection optics box (POB)) 30 and a substrate stage 24, in accordance with some embodiments. The elements of the lithography exposure system 10 can be added to or omitted, and the disclosure should not be limited by the embodiment.

The light source 120 is configured to generate light radiation having a wavelength ranging between about 1 nm and about 100 nm in certain embodiments. In one particular example, the light source 120 generates an EUV radiation with a wavelength centered at about 13.5 nm. Accordingly, the light source 120 is also referred to as an EUV radiation source. However, it should be appreciated that the light source 120 should not be limited to emitting EUV radiation. The light source 120 can be utilized to perform any high-intensity photon emission from excited target fuel.

In various embodiments, the illuminator 140 includes various refractive optic components, such as a single lens or a lens system having multiple reflectors 100, for example lenses (zone plates) or alternatively reflective optics (for EUV lithography exposure system), such as a single mirror or a mirror system having multiple mirrors in order to direct light from the light source 120 onto the mask stage 16, particularly to a mask 18 secured on the mask stage 16. In embodiments in which the light source 120 generates light in the EUV wavelength range, reflective optics are employed. In some embodiments, the illuminator 140 includes at least two lenses, at least three lenses, or more.

The mask stage 16 is configured to secure the mask 18. In some embodiments, the mask stage 16 includes an electrostatic chuck (e-chuck) to secure the mask 18. One reason an e-chuck is beneficial is that gas molecules absorb EUV radiation and the e-chuck is operable in the lithography exposure system for the EUV lithography patterning that is maintained in a vacuum environment to avoid EUV intensity loss. In the present disclosure, the terms mask, photomask, and reticle are used interchangeably. In the present embodiment, the mask 18 is a reflective mask. One exemplary structure of the mask 18 includes a substrate with a suitable material, such as a low thermal expansion material (LTEM) or fused quartz. In various examples, the LTEM includes TiO₂ doped SiO₂, or other suitable materials with low thermal expansion. The mask 18 includes a reflective multilayer deposited on the substrate. The mask stage 16 is operable to translate in two horizontal directions, such as an X-axis direction and a Y-axis direction, so as to expose multiple different regions of the semiconductor wafer 22 to light having a pattern generated by the mask 18. The semiconductor wafer 22 may have a mask layer 26 thereon, which may be a photoresist layer that is sensitive to the light carrying the pattern of the mask 18.

The projection optics module (or projection optics box (POB)) 30 is configured for imaging the pattern of the mask 18 on to a semiconductor wafer 22 secured on the substrate stage 24 of the lithography exposure system 10. In some embodiments, the POB 30 has refractive optics (such as for a UV lithography exposure system) or alternatively reflective optics (such as for an EUV lithography exposure system) in various embodiments. The light directed from the mask 18, carrying the image of the pattern defined on the mask, is collected by the POB 30. The illuminator 140 and the POB 30 are collectively referred to as an optical module of the lithography exposure system 10. In some embodiments, the POB 30 includes at least six reflective optics.

In some embodiments, the semiconductor wafer 22 may be made of silicon or other semiconductor materials. Alternatively or additionally, the semiconductor wafer 22 may include other elementary semiconductor materials such as germanium (Ge). In some embodiments, the semiconductor wafer 22 is made of a compound semiconductor such as silicon carbide (SiC), gallium arsenic (GaAs), indium arsenide (InAs), or indium phosphide (InP). In some embodiments, the semiconductor wafer 22 is made of an alloy semiconductor such as silicon germanium (SiGe), silicon germanium carbide (SiGeC), gallium arsenic phosphide (GaAsP), or gallium indium phosphide (GaInP). In some other embodiments, the semiconductor wafer 22 may be a silicon-on-insulator (SOI) or a germanium-on-insulator (GOI) substrate.

In addition, the semiconductor wafer 22 may have various device elements. Examples of device elements that are formed in the semiconductor wafer 22 include transistors (e.g., metal oxide semiconductor field effect transistors (MOSFET), complementary metal oxide semiconductor (CMOS) transistors, bipolar junction transistors (BJT), high voltage transistors, high-frequency transistors, p-channel and/or n-channel field-effect transistors (PFETs/NFETs), etc.), diodes, and/or other applicable elements. Various processes are performed to form the device elements, such as deposition, etching, implantation, photolithography, annealing, and/or other suitable processes. In some embodiments, the semiconductor wafer 22 is coated with a resist layer sensitive to the EUV radiation. Various components including those described above are integrated together and are operable to perform lithography processes.

The lithography exposure system 10 may further include other modules or be integrated with (or be coupled with) other modules, such as a cleaning module designed to provide hydrogen gas to the light source 120. The hydrogen gas helps reduce contamination in the light source 120. Further description of the light source 120 is provided with reference to FIG. 1B.

In FIG. 1B, the light source 120 is shown in a diagrammatical view, in accordance with some embodiments. In some embodiments, the light source 120 employs a dual-pulse laser produced plasma (LPP) mechanism to generate plasma 88 and further generate EUV radiation from the plasma. The light source 120 includes a droplet generator 30, a droplet receptacle 35, a laser generator 50, a laser produced plasma (LPP) collector 60, a monitoring device 70 and a controller 90. Some or all of the above-mentioned elements of the light source 120 may be held under vacuum. It should be appreciated that the elements of the light source 120 can be added to or omitted, and should not be limited by the embodiment.

The droplet generator 30 is configured to generate a plurality of droplets 82, which may be elongated, of a target fuel 80 to a zone of excitation at which at least one laser pulse 51 from the laser generator 50 hits the droplets 82 along an x-axis, as shown in FIG. 1B. In an embodiment, the target fuel 80 includes tin (Sn). In an embodiment, the droplets 82 may be formed with an elliptical shape. In an embodiment, the droplets 82 are generated at a rate of about 50 kilohertz (kHz) and are introduced into the zone of excitation in the light source 120 at a speed of about 70 meters per second (m/s). Other material can also be used for the target fuel 80, for example, a tin containing liquid material such as eutectic alloy containing tin, lithium (Li), and xenon (Xe). The target fuel 80 in the droplet generator 30 may be in a liquid phase.

The laser generator 50 is configured to generate at least one laser pulse to allow the conversion of the droplets 82 into plasma 88. In some embodiments, the laser generator 50 is configured to produce a laser pulse 51 to the lighting point 52 to convert the droplets 82 to plasma 88 which generates EUV radiation 84. The laser pulse 51 is directed through window (or lens) 55, and irradiates droplets 82 at the lighting point 52. The window 55 is formed in the sectional collector 60 and adopts a suitable material substantially transparent to the laser pulse 51. The droplet receptacle 35 catches and collects unused droplets 82 and/or scattered material of the droplets 82 resulting from the laser pulse 51 striking the droplets 82.

The plasma emits EUV radiation 84, which is collected by the collector 60. The collector 60 further reflects and focuses the EUV radiation 84 for the lithography processes performed through an exposure tool. In some embodiments, the collector 60 has an optical axis 61 which is parallel to the z-axis and perpendicular to the x-axis. The collector 60 may includes a single section, as shown, or at least two sections that are offset from each other in the z-axis direction. The collector 60 may further include a vessel wall 65 having first and second pumps 66, 68 attached thereto. In some embodiments, the first and second pumps 66, 68 include scrubbers configured to remove particulates and/or gases from the collector 60. The first and second pumps 66, 68 may be collectively referred to as “the pumps 66, 68” herein.

In an embodiment, the laser generator 50 is a carbon dioxide (CO2) laser source. In some embodiments, the laser generator 50 is used to generate the laser pulse 51 with single wavelength. The laser pulse 51 is transmitted through an optic assembly for focusing and determining incident angle of the laser pulse 51. In some embodiments, the laser pulse 51 has a spot size of about 200-300 μm, such as 225 μm. The laser pulse 51 is generated to have certain driving power to meet wafer production targets, such as a throughput of 125 wafers per hour (WPH). For example, the laser pulse 51 is equipped with about 23 kW driving power. In various embodiments, the driving power of the laser pulse 51 is at least 20 kW, such as 27 kW.

The monitoring device 70 is configured to monitor one or more conditions in the light source 70 so as to produce data for controlling configurable parameters of the light source 120. In some embodiments, the monitoring device 70 includes a metrology tool 71 and an analyzer 73. In cases where the metrology tool 71 is configured to monitor condition of the droplets 82 supplied by the droplet generator 30, the metrology tool may include an image sensor, such as a charge coupled device (CCD), complementary metal oxide semiconductor sensor (CMOS) sensor or the like. The metrology tool 71 produces a monitoring image including image or video of the droplets 82 and transmits the monitoring image to the analyzer 73. In cases where the metrology tool 71 is configured to detect energy or intensity of the EUV light 84 produced by the droplet 82 in the light source 12, the meteorology tool 71 may include a number of energy sensors. The energy sensors may be any suitable sensors that are able to observe and measure energy of electromagnetic radiation in the ultraviolet region.

The analyzer 73 is configured to analyze signals produced by the metrology tool 71 and outputs a detection signal to the controller 90 according to an analyzing result. For example, the analyzer 73 includes an image analyzer. The analyzer 73 receives the data associated with the images transmitted from the metrology tool 71 and performs an image analysis process on the images of the droplets 82 in the excitation zone. Afterwards, the analyzer 73 sends data related to the analysis to the controller 90. The analysis may include a flow path error or a position error.

In some embodiments, two or more metrology tools 71 are used to monitor different conditions of the light source 120. One is configured to monitor condition of the droplets 82 supplied by the droplet generator 30, and the other is configured to detect energy or intensity of the EUV light 84 produced by the droplet 82 in the light source 120. In some embodiments, the metrology tool 71 is a final focus module (FFM) and positioned in the laser source 50 to detect light reflected from the droplet 82.

The controller 90 is configured to control one or more elements of the light source 120. In some embodiments, the controller 90 is configured to drive the droplet generator 30 to generate the droplets 82. In addition, the controller 90 is configured to drive the laser generator 50 to fire the laser pulse 51. The generation of the laser pulse 51 may be controlled to be associated with the generation of droplets 82 by the controller 90 so as to make the laser pulse 51 hit each target 82 in sequence.

In some embodiments, the droplet generator 30 includes a reservoir 31 and a nozzle assembly 32. The reservoir 31 is configured for holding the target material 80. In some embodiments, one gas line 41 is connected to the reservoir 31 for introducing pumping gas, such as argon, from a gas source 40 into the reservoir 31. By controlling the gas flow in the gas line 41, the pressure in the reservoir 31 can be manipulated. For example, when gas is continuously supplied into the reservoir 31 via the gas line 41, the pressure in the reservoir 31 increases. As a result, the target material 80 in the reservoir 31 can be forced out of the reservoir 31 in the form of droplets 82.

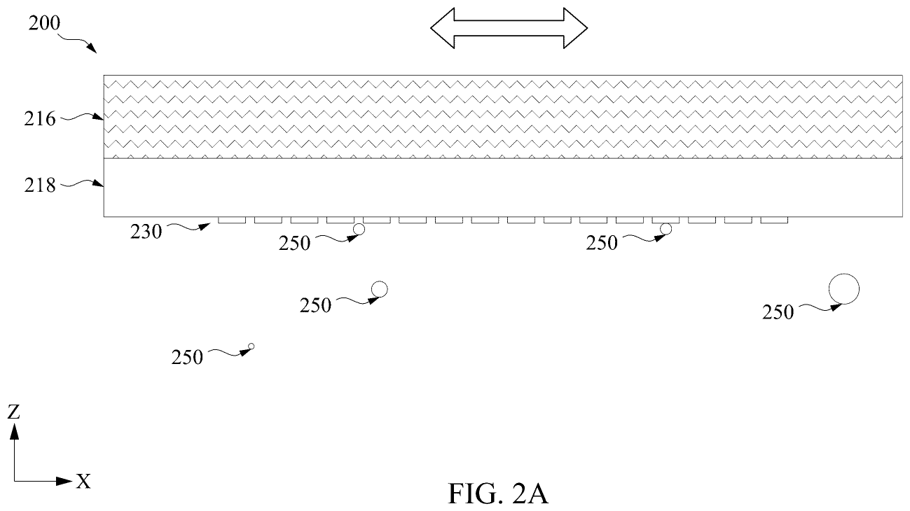

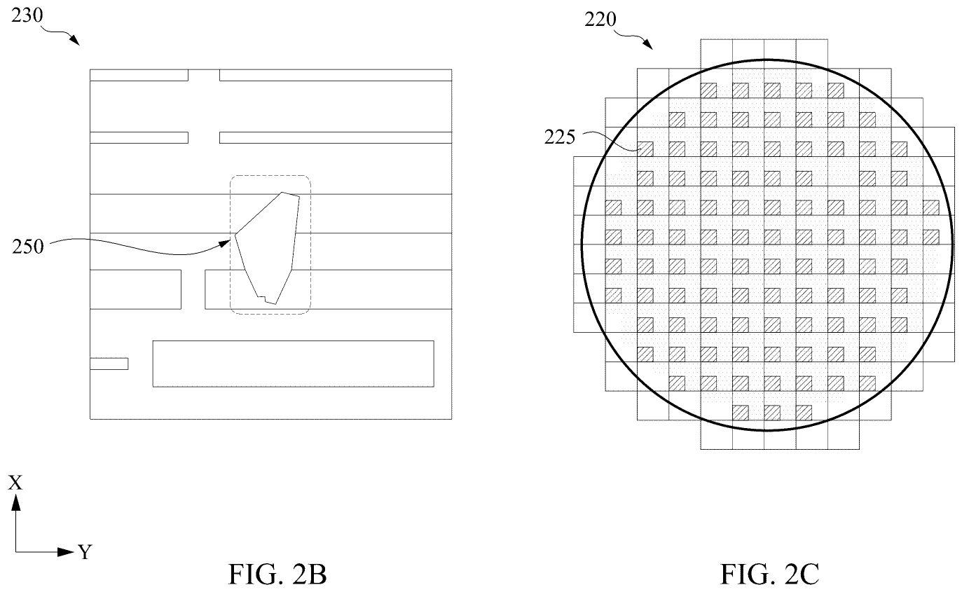

FIGS. 2A-2C are views of various embodiments of a mask assembly 200 of a lithography scanner according to various aspects of the present disclosure. FIG. 2A is a side view of a mask assembly 200. FIG. 2B is a top view of a mask pattern 230 of the mask assembly 200. FIG. 2C is a diagram illustrating exposure errors in regions 225 of a semiconductor wafer 220.

In FIG. 2A, the mask assembly 200 includes a mask stage 216 and a mask 218 attached thereto. The mask stage 216 and the mask 218 may be the mask stage 16 and the mask 18, respectively, of FIGS. 1A and 1B. The mask 218 includes mask patterns 230 that may be located in a layer of the mask 218 facing reflectors of the illuminator 140 and the POB 30 on either side of the mask assembly 200.

Particles 250 may be present in the lithography scanner. The particles 250 may include different types of particles generated by different sources in the lithography scanner. For example, the particles 250 may include tin particles generated by the light source 120 during formation of the plasma 88. The particles 250 may include SiC particles generated by movement of the mask assembly 200 in the X-and Y-axis directions. The particles 250 may include carbon particles generated by a pod or carrier used for transporting the mask 218 in and out of the lithography scanner. Other particles 250 having different material composition may be generated by other sources internal or external to the lithography scanner. One or more of the particles 250 may settle on the surface of the mask 218 on one or more mask pattern regions of the mask patterns 230. The particles 250 that settle on the reticle surface form reticle defects that can lead to pattern failure in all exposure fields (e.g., regions 225 of FIG. 2C) of a wafer.

FIG. 2B shows a view of the mask patterns 230 with a particle 250 thereon. The mask patterns 230 are exposed to the internal environment of the lithography scanner. While the mask assembly 200 is in the lithography scanner, the particle 250 may fall on the mask 218. The particle 250 may form a short circuit or bridge or merger between one or more pattern regions of the mask patterns 230. When the pattern of the mask 218 is transferred to a semiconductor wafer, an electrical defect, such as a short circuit or bridge or merger, may occur between features of the semiconductor wafer. For example, neighboring semiconductor fins or neighboring conductive traces may merge unintentionally, which may result in failure of an integrated circuit die formed in the semiconductor wafer.

FIG. 2C shows a diagrammatic view of a semiconductor wafer 220, which may be the semiconductor wafer 22 of FIGS. 1A and 1B. The view of FIG. 2C may be a diagram of an image generated by a metrology tool that analyzes the semiconductor wafer 220. During exposure, in which light carrying the pattern of the mask patterns 230 is incident on the semiconductor wafer 220, the particle 250 alters the pattern, which is transferred repeatedly onto some or all of the regions 225 of the semiconductor wafer 220. As such, quality of the semiconductor wafer 220 is reduced, reducing productivity of the lithography scanner.

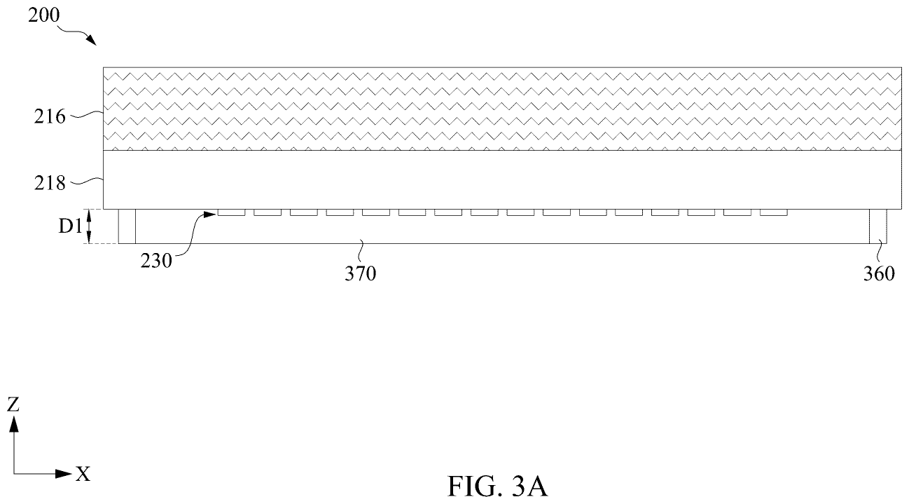

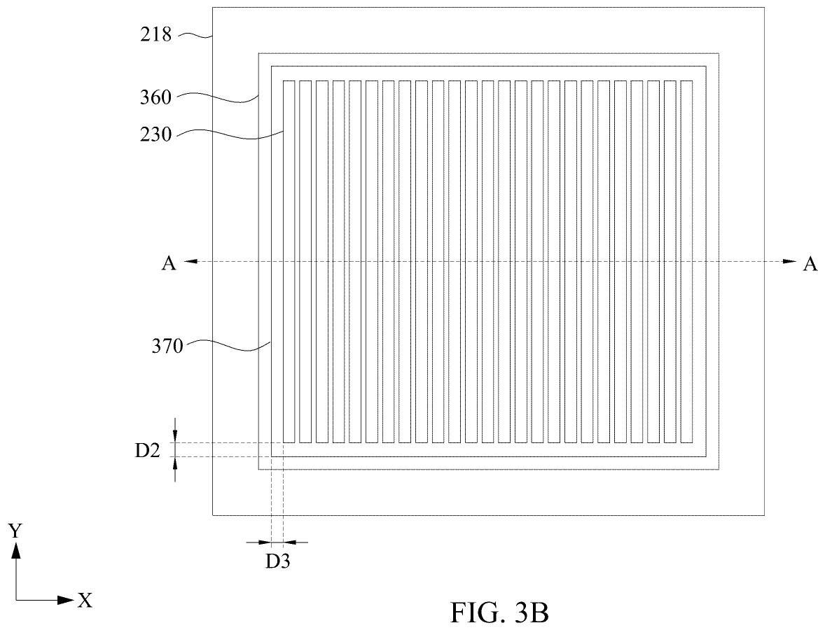

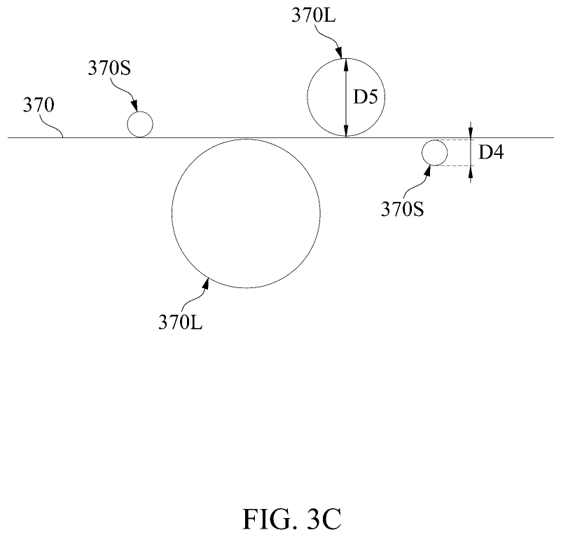

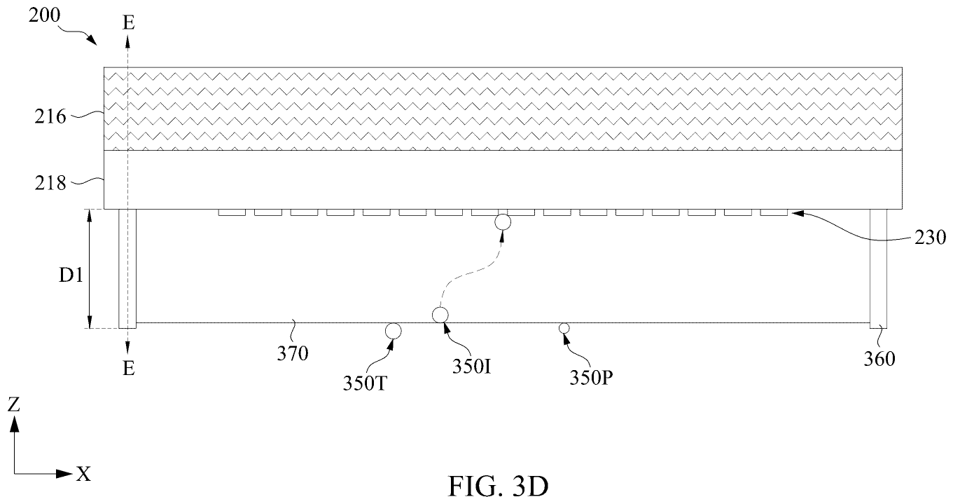

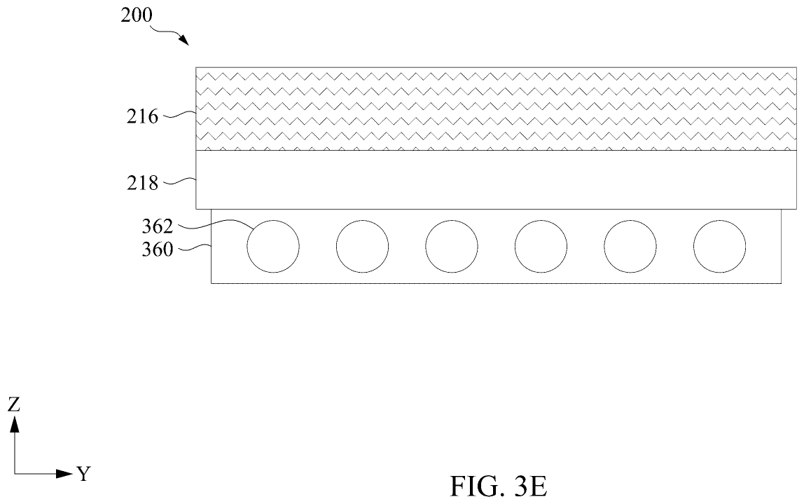

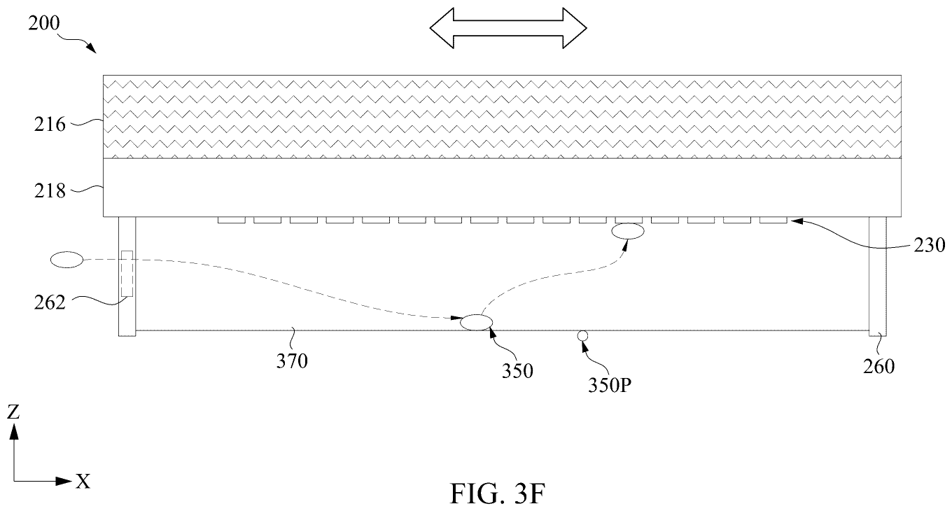

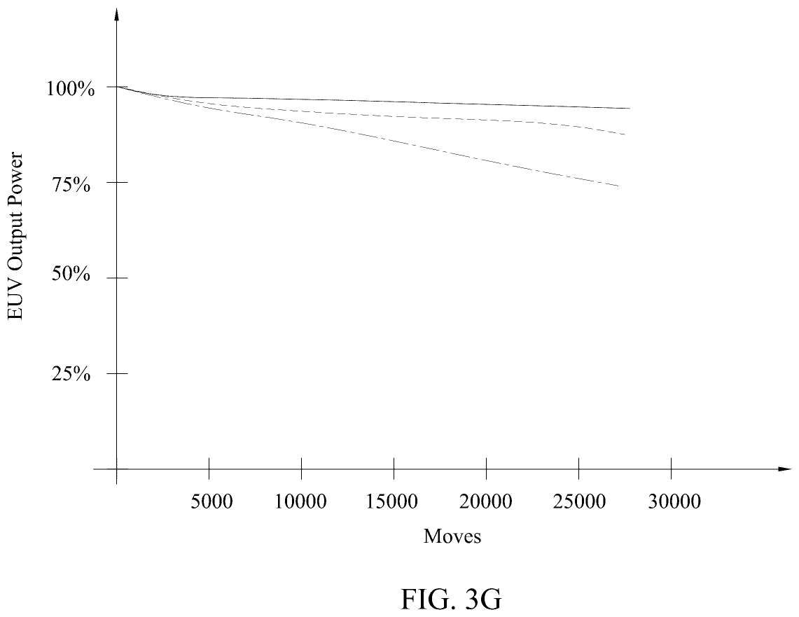

FIGS. 3A-3G are diagrammatic views showing a pellicle 370 and frame 360 installed on the mask assembly 200 to prevent the particles 250 from attaching to the mask 218. In FIGS. 3A and 3B, the pellicle 370 is shown suspended by the frame 360 over the mask patterns 230. The pellicle 370 may be a nanoscale thickness thin film that has high transparency (e.g., >90%) to EUV wavelengths (e.g., 13.5 nm). For example, the pellicle 370 may have thickness in the Z-axis direction in a range of about 1 nm to about 10 nm.

The frame 360 has height D1, which may be in a range of about 1 millimeter to about 3 millimeters, or more. The height D1 is about the same as a separation distance between the pellicle 370 and the mask patterns 230 in the Z-axis direction. The frame 360 may have rectangular (e.g., square) shape in the XY-plane, as shown in FIG. 3B. The frame 360 may be adjacent to the mask patterns 230 on four sides, as shown. The frame 360 may be offset horizontally in the X-axis and Y-axis directions from the mask patterns 230. For example, the frame 360 may be offset from the mask patterns by a second distance D2 in the Y-axis direction and by a third distance D3 in the X-axis direction. The distances D1, D2, D3 may be the same as each other. In some embodiments, one or more of the distances D1-D3 is different from others of the distances D1-D3. For example, the distance D1 may be in the range of about 1-3 millimeters as described above, and the second and third distances D2, D3 may be in a range of about 0.5 millimeters to about 10 millimeters. Mounting the pellicle 370 on the frame 360 can prevent mask defects formed by particles released by the lithography scanner. Generally, the distance D1 is sufficiently large such that any particle 250 less than a selected size (e.g., diameter less than about 500 nm) that settles on the outside surface of the pellicle 370 is far enough from a focal plane of incident light that the particle 250 does not cause a pattern defect failure.

FIG. 3C illustrates presence of particles 370S, 370L on the pellicle 370. The particles 370S, 370L may include small particles 370S and large particles 370L. The small particles 370S may have diameter D4 that is less than a particle detection resolution of an inspection tool, and the large particles 370L may have a diameter D5 that is greater than the particle detection resolution. The particles 370S, 370L may be the same as the particles 250 described above with reference to FIGS. 2A-2G. Prior to mounting the pellicle 370 onto the mask assembly 200, an inspection process may be performed by the inspection tool for pellicle qualification. The qualification process may have a particle detection range or resolution outside of which, particles may not be identified. For example, the particle detection resolution may be about 300 nm. The diameter D4 of the small particles 370S may be less than 300 nm, such as less than 200 nm, less than 100 nm, less than 50 nm, or the like. The diameter D5 of the large particles 370L may be greater than 300 nm. As such, the large particles 370L on the inside and outside surfaces of the pellicle 370 may be identified by the inspection tool, and the small particles 370S may not be identified by the inspection tool, and may remain on the pellicle 370 when mounted.

After mounting the pellicle 370, further inspection by the inspection tool may damage the pellicle 370, due to the pellicle 370 being under tension, making it easily ruptured by fluctuation and external vibration. As such, the small particles 370S may remain on the inside and outside surfaces of the pellicle 370 after the pellicle 370 is mounted to the mask assembly 200.

FIG. 3D illustrates the mask assembly 200 with the pellicle 370 mounted thereto after a period of operation. Generally, the pellicle 370 may be operated for a selected number of wafers before being replaced. For example, the pellicle 370 may be said to have a “lifetime” of about 10,000 wafers, about 15,000 wafers, or the like. In another example, the pellicle 370 may have a lifetime measured in number of moves or translations. Exposure of all regions of a single wafer may include tens, hundreds or thousands of moves. During manufacture of integrated circuit dies on the semiconductor wafer 220, the mask assembly 200 may translate back and forth along the XY plane, and particles 350T, 350P may attach to the outside surface of the pellicle 370, as shown in FIG. 3D. The particles 350T, 350P may include tool particles 350T and pod particles 350P, among other particle types described above with reference to FIGS. 2A-2G. Over time, as the particles 350T, 350P accumulate on the pellicle 370, and due to repeated acceleration along the XY plane of the pellicle 370, the pellicle 370 may deform or rupture and be replaced.

One or more inner particles or “IOPD” 350I may be on an inner surface of the pellicle 370 that faces the reticle 218. As described above with reference to FIG. 3C, the inner particles 350I may be small particles 350S that are present on the pellicle 370 prior to and following mounting. For example, the IOPD 350I may be formed during a thin film process that forms the pellicle 370 or may be induced during mounting of the pellicle 370 to the reticle 218. In another example, the inner particles 350I may be due to bond breaking of pellicle elements after EUV exposure. In yet another example, the inner particles 350I may be tool particles 350T or pod particles 350P that enter the space between the frame 360, the pellicle 370 and the reticle 218, which is described in greater detail with reference to FIGS. 3E and 3F.

FIGS. 3E and 3F illustrate a side view of the frame 360 (FIG. 3E) and formation of inner pellicle defects due to openings or holes 362 in the frame 360 (FIG. 3F). Because the pellicle 370 is operated in a vacuum or near-vacuum environment, the holes 362 are present in the frame 360 that are beneficial to balance pressure between the space underneath the pellicle 370 and an internal environment of the lithography scanner in which the mask assembly 200 is disposed. Without the holes 362, the pellicle 370 would be prone to rupture in the vacuum or near-vacuum environment due to air pressure in the space underneath the pellicle 370 between the pellicle 370 and the mask patterns 230 following mounting of the pellicle 370 to the mask 218.

As shown in FIG. 3F, due to the holes 362 in the frame 360, a particle 350 may enter the space between the pellicle 370 and the mask patterns 230 through the holes 362. The particle 350 may settle on the inside surface of the pellicle 370, then may fall and settle on the mask patterns 230. The particle 350 illustrated in FIG. 3F may be referred to as an “inner pellicle defect.” The inner pellicle defect is difficult to detect, and may lead to significant reduction of yield.

FIG. 3G is a diagram that illustrates loss of output power of light incident on the semiconductor wafer 220 relative to number of moves of the mask assembly 200 during processing of wafers. For example, output power of the light source 120 may be about 250 Watts, and after 20,000 moves of the mask assembly 200, due to accumulation of particles on the pellicle 370, effective output power may be reduced by about 5% to about 238 Watts. As shown in FIG. 3G, decay of the pellicle 370 may vary significantly from pellicle to pellicle, batch to batch, lot to lot, or the like, which may increase difficulty in estimating output power and controlling for (e.g., compensating for) the reduction in output power relative to number of moves. For example, if decay of the output power over the lifetime of the pellicle 370 were well known, exposure time could be increased based on the decay relative to the number of moves.

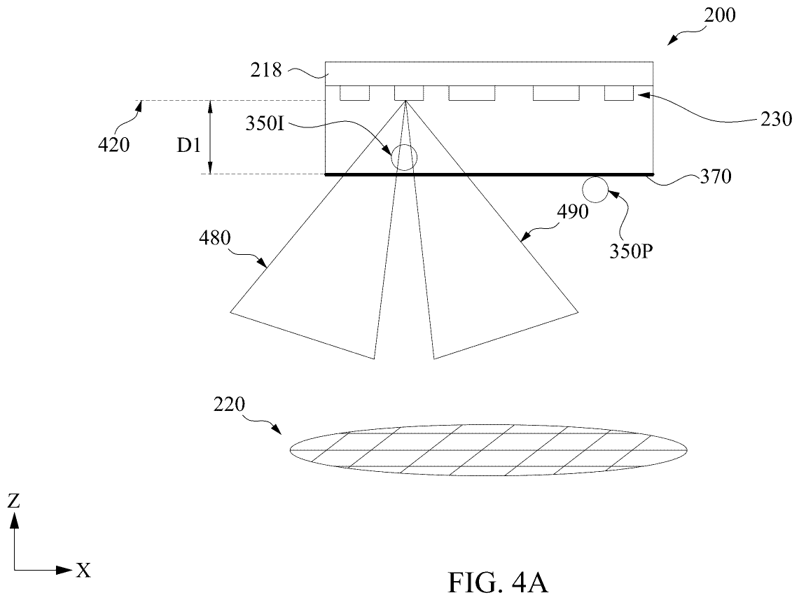

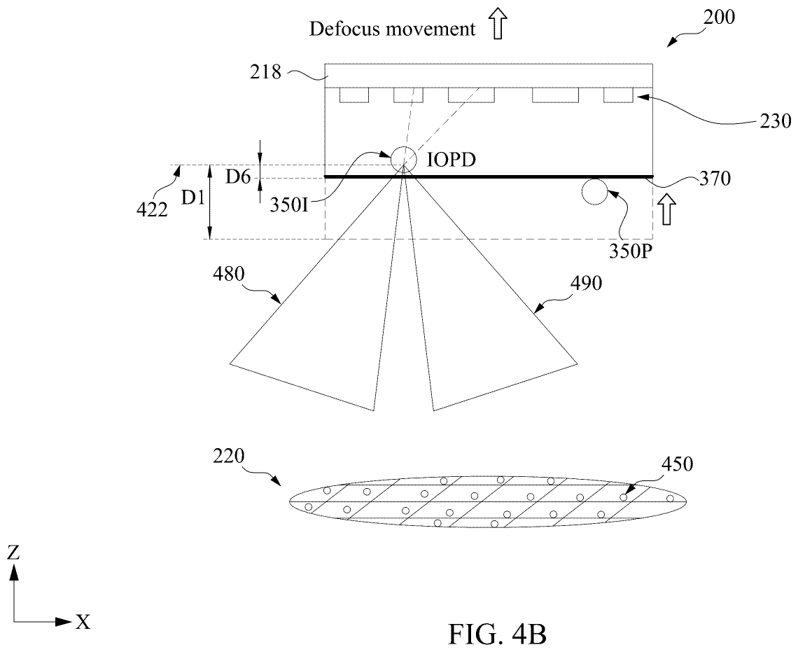

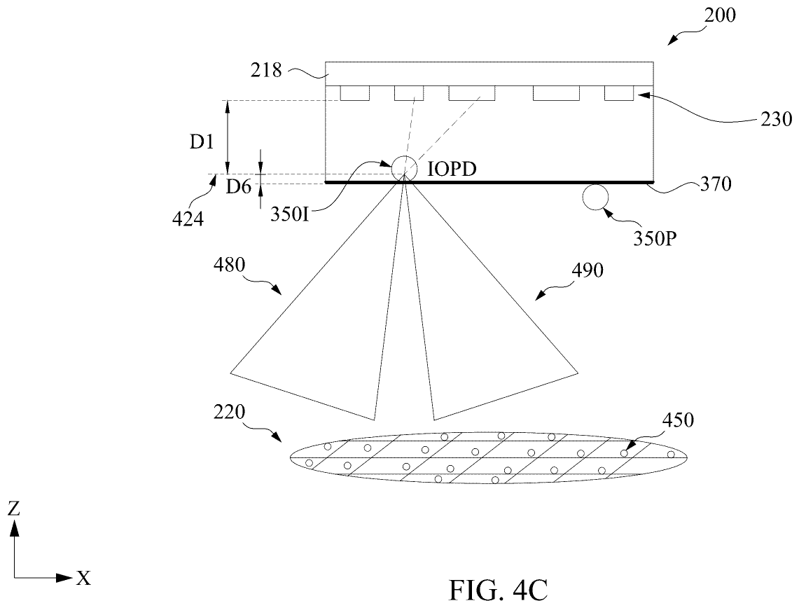

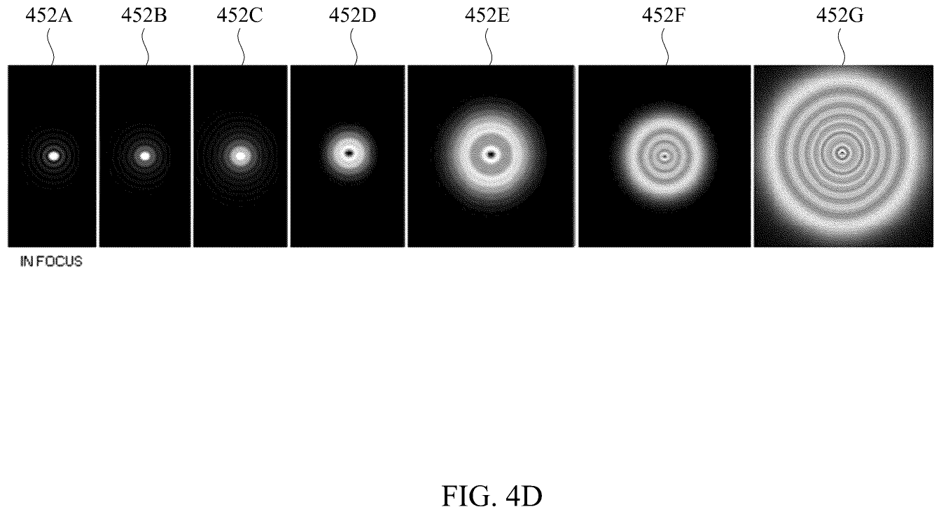

FIGS. 4A-4D are diagrams illustrating a method of detecting an IOPD 350I in accordance with various embodiments. FIG. 4A shows exposure of a wafer 220 during semiconductor device fabrication by light 490 reflected from the reticle 218 when a focal plane 420 of incident light 480 is level with the mask pattern 230 of the reticle 218. FIG. 4B shows exposure of the wafer 220 by the light 490 reflected from the inner particle 350I when a focal plane 422 of the incident light 480 is substantially level with or offset slightly from the pellicle 370 due to defocus movement of the mask assembly 200. FIG. 4C shows exposure of the wafer 220 by the light 490 reflected from the inner particle 350 when a focal plane 424 of the incident light 480 is substantially level with or offset slightly from the pellicle 370 due to defocusing of the incident light 480. FIG. 4D is a diagram illustrating various defocus images 452A-452G associated with different distances from an inner particle 350I.

In FIG. 4A, the wafer 220 may be exposed by light 490 that carries a pattern of the reticle 218 generated by the mask pattern 230. The light 490 may be reflected by multiple reflectors, such as reflectors of the POB 30, before hitting the wafer 220. The light 490 may be incident on a mask layer, such as a photoresist layer, on the wafer 220. The pattern of the reticle 218 may be transferred to the photoresist layer on the wafer 220 by exposure of the photoresist layer to the light 490. Because the inner particle 350I is far from the focal plane 420, deviation from the pattern in the light 490 due to the inner particle 350I is reduced to a level that is unlikely to result in pattern failure. This is shown in FIG. 4A by an absence of particle patterns 450 on the wafer 220. Due to the inner particle 350I being far from the focal plane 420, it may be difficult to identify or detect presence of the inner particle 350I using the incident light 480 having the focal plane 420 located at a large distance (e.g., about the distance D1) from the inner particle 350I. It should be understood that FIGS. 4A-4C are not drawn to scale for ease of illustration. As described above with reference to FIGS. 3A-3G, the distance D1 may be in a range of about 1 mm to about 3 mm, and the inner particle 350I may have diameter less than about 300 nm. Namely, a ratio of separation D1 of the inner particle 350I from the focal plane 420 to diameter of the inner particle 350I may be in a range of about 3,000 to about 10,000.

In FIG. 4B, the incident light 480 is “defocused” from the mask pattern 230, the inner particle 350I, or both, which is advantageous to detect the inner particle 350I on the pellicle 370. The defocusing may be performed by shifting position of the mask assembly 200 relative to a reflector that directs the incident light 480 toward the reticle 218. The shifting position may be accomplished by an actuator (not shown) that is operable to move the mask assembly 200 in a vertical direction (e.g., a Z-axis direction) that is orthogonal to the XY plane. In some embodiments, the shifting position may be by the distance D1. In some embodiments, another distance is used for the shifting position instead of the distance D1.

As shown in FIG. 4B, the incident light 480 may have a focal plane 422 after defocusing that is at a level between the pellicle 370 and the mask pattern 230. In some embodiments, the focal plane 422 is at or near a center of the inner particle 350I. The center may be a predicted center. For example, presence or absence of the inner particle 350I, number of inner particles 350I on the pellicle 370 and respective sizes of the inner particle(s) 350I may be unknown prior to detection.

To detect the inner particle(s) 350I on the inner surface of the pellicle 370, the focal plane 422 may be positioned at one or more different levels, each of which may have attendant advantages. For example, the level may be a distance D6 offset from the pellicle 370 in a direction toward the reticle 218, as shown. The distance D6 may be half a resolution of the inspection tool described with reference to FIG. 3C. For example, when the inspection tool has resolution of 300 nm, the distance D6 may be about 150 nm.

In some embodiments, the distance D6 is substantially zero, such that the focal plane 422 is substantially coplanar with the pellicle 370.

In some embodiments, the distance D6 is between the half a resolution and zero. For example, the distance D6 may be associated with a selected particle size that is not large enough to cause a pattern failure when the inner particle 350I of the selected particle size settles on the mask pattern 230. For example, the selected particle size may be about 4 nm, and the distance D6 may be about 2 nm, or half the selected particle size.

In some embodiments, a database may store historical inner particle data based on historic inner particle detection operations. The historical inner particle data may include size information about inner particles detected in the historic inner particle detection operations. Based on the size information, an average size, a median size, a most common size, or other suitable size may be determined. In such embodiments, the distance D6 may be about half the average size, half the median size, half the most common size, or half the other suitable size.

In some embodiments, multiple exposures using more than one of the distances D6 described above are performed. For example, a first exposure may be performed at the distance D6 of 150 nm, a second exposure may be performed at the distance D6 of 10 nm, and a third exposure may be performed at the distance D6 of 2 nm.

In some embodiments, a first position of the mask assembly 200 that is associated with the focal plane 420 is stored in a database, and a second position of the mask assembly 200 that is associated with the focal plane 422 is stored in the database. During semiconductor processing of production wafers, the mask assembly 200 may be positioned at the first position, and during detection of inner particles 350I, the mask assembly 200 may be positioned at the second position.

In some embodiments, exposure by the light 490 is on a photoresist layer of a wafer, such as the wafer 220. In some embodiments, the exposure is on an image sensor of a camera, such as an EUV camera. In some embodiments, the EUV camera is an EUV wavefront camera. The EUV wavefront camera may include a plurality of microlenses over an image sensor. The EUV wavefront camera may be a quadri-wave lateral shearing interferometer (QWLSI) camera.

It should be understood from the above description that the focal plane 422 may overlap one or more of the inner particles 350I and/or may be defocused (i.e., underfocused) relative to one or more of the inner particles 350I. FIG. 4D shows example diffraction images or “defocus patterns” 452A, 452B, 452C, 452D, 452E, 452F, 452G, associated with increasing underfocus relative to a subject (e.g., the inner particle 350I). The diffraction image 452A is associated with the focal plane 422 passing through (overlapping) the inner particle 350I. The diffraction image 452B is associated with the focal plane 422 being between the inner particle 350I and the reticle 218. The diffraction images 452C, 452D, 452E, 452F and 452G are associated with the focal plane 422 being increasing distant from the inner particle 350I.

When the wafer 220 is exposed by the light 490, one or more points (e.g., the diffraction image 452A) may be transferred to the photoresist layer, one or more defocus patterns shown in the diffraction images 452B-452G may be transferred to the photoresist layer, or a combination thereof. Example defocus patterns 450 are illustrated in FIG. 4B. An inspection tool, such as an optical inspection tool, may then take an image of the photoresist layer, and identify presence or absence of the inner particles 350I based on the image. In some embodiments, the one or more points or defocus patterns are transferred to the image sensor of the EUV camera or the EUV wavefront camera, which may take a camera image thereof. When the camera image is taken by the EUV wavefront camera, an algorithm may be performed to calculate dynamics of the defocus pattern(s) of the camera image. The dynamics may include number of rings, intensity of the rings, and the like of the defocus pattern(s).

As shown in FIG. 4C, the incident light 480 may have a focal plane 424 after defocusing that is at a level between the pellicle 370 and the mask pattern 230. Details of the focal plane 424 may be similar to or the same as those of the focal plane 422 described with reference to FIG. 4B. The focal plane 424 may be offset from the pellicle 370 in the direction of the reticle 218 by the distance D6. Details of the distance D6 may be similar to or the same as those of the distance D6 described with reference to FIG. 4B.

The incident light 480 may have the focal plane 424 by defocusing the incident light 480 itself instead of moving the mask assembly 200. Defocusing the incident light 480 may be performed by modifying an optical path that generates the incident light 480. For example, the reflector (e.g., the reflector 100 of FIG. 1A) that directs the incident light 480 may be moved to a second position further from the mask assembly 200 than a first position that is used during semiconductor processing operations (e.g., the position that generates the incident light 480 shown in FIG. 4A). Namely, the first position is associated with the focal plane 420 that is on or very near the mask pattern 230, and the second position is associated with the focal plane 424 that is on or near the pellicle 370. Another reflector of the illuminator 140, the collector 60 of the light source 120, another element along the optical path, or a combination thereof may be shifted to one or more third positions that are associated with generating the focal plane 424 that is on or near the pellicle 370. In addition to shifting one or more of the elements just described, respective angles of the one or more elements may also be rotated. In some embodiments, a first set of respective angles and positions of the one or more elements that is associated with the focal plane 420 is stored in a database, and a second set of respective angles and positions of the one or more elements that is associated with the focal plane 424 is stored in the database. During semiconductor processing of production wafers, the one or more elements may be positioned and rotated based on the first set, and during detection of inner particles 350I, the one or more elements may be positioned and rotated based on the second set.

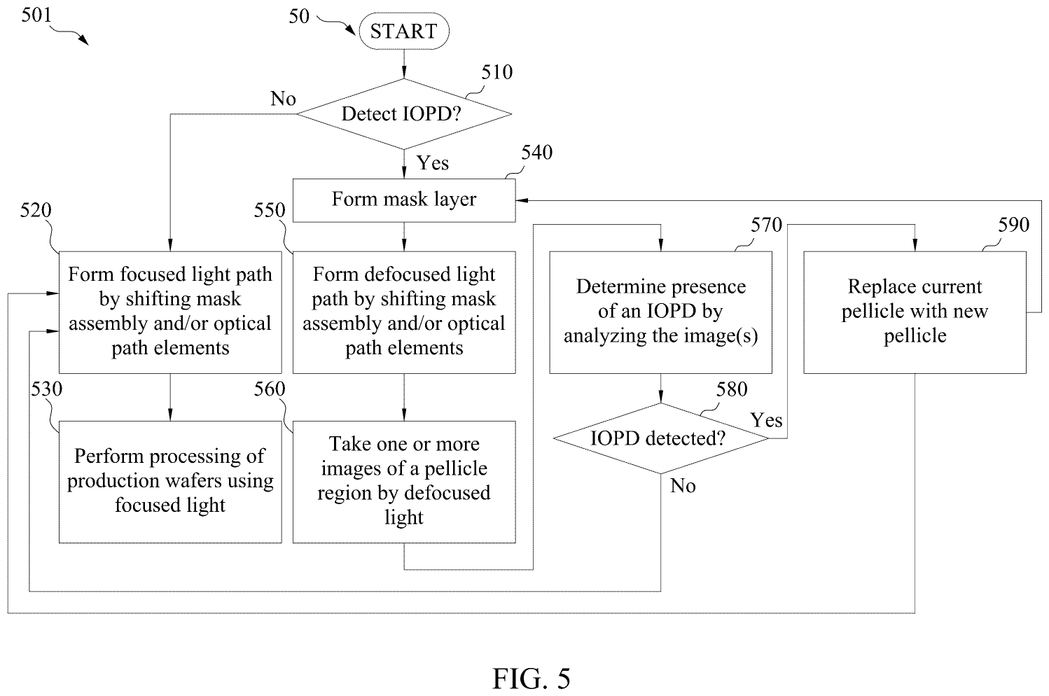

FIG. 5 is a flowchart of a process or method 501 for forming a device in accordance with various embodiments. In some embodiments, the process 501 for forming the device includes a number of operations (50, 510, 520, 530, 540, 550, 560, 570, 580 and 590). The process 501 for forming the device will be further described according to one or more embodiments. It should be noted that the operations of the process 501 may be rearranged or otherwise modified within the scope of the various aspects. It should further be noted that additional processes may be provided before, during, and after the process 501, and that some other processes may be only briefly described herein. In some embodiments, the process 501 is performed by the lithography exposure system 10 described in FIGS. 1A-3B. The embodiments are described with reference to the structural elements and processes described in FIGS. 1A-4D, but the process 501 may be performed by a lithography system having one or more structural elements that are different from those of the lithography system 10.

The method 501 begins at operation 50. When an inner particle 350I is to be detected in operation 510, the method proceeds to operation 540. When detection is not to be performed, the method proceeds to operation 520. Determining whether an inner particle 350I is to be detected may be performed on a selected schedule. For example, the selected schedule may include a number of wafers processed, a number of moves performed by the mask assembly, or another schedule. The selected schedule may be a number of moves that is less than an expected lifetime of the pellicle 370. For example, the expected lifetime of the pellicle 370 may be in a range of about 10,000 moves to about 50,000 moves, and the number of moves of the selected schedule may be 1000 moves, 5000 moves, fewer moves or more moves. Then, every 1000 moves, for example, operation 510 may proceed to operation 540. The selected schedule may be every 99 production wafers processed, or another suitable number of production wafers. In the example of 99 production wafers, the ratio of wafers consumed in detection of inner particles 350I may be 1/100. Another ratio may be used, and may be determined based on advantageous ability to detect inner particles 350I, cost of wafers consumed in detection of inner particles 350I, or the like.

In operation 520, a focused light path is formed by shifting the mask assembly 200, one or more elements of the lithography system 10, or both. The shifting may include shifting position, shifting rotation, or both. The shifting may be performed in the manner described with reference to FIGS. 4A-4D. The shifting may result in the incident light 480 having the focal plane 420 that coincides with the mask pattern 230.

In operation 530, following forming the focused light path, processing of production wafers is performed using focused light. The focused light includes the incident light 480 having the focal plane 420. The processing may include deposition of a mask layer (e.g., a photoresist) on the wafer 22, exposing the mask layer to the light 490 carrying the pattern of the mask pattern 230, patterning the mask layer based on the pattern, etching a layer underlying the patterned mask layer to form openings, and forming features in the openings. The features may include shallow trench isolations (STIs), source/drain regions, gate structures, conductive contacts, conductive vias, conductive traces, or the like.

In operation 540, when inner particles 350I are to be detected, a mask layer (e.g., a mask layer 26 shown in FIG. 1A) is deposited over a substrate, such as the wafer 22. In some embodiments, the mask layer 26 includes a photoresist layer that is sensitive to the EUV radiation 84. In some embodiments, the substrate is a semiconductor substrate, such as the semiconductor wafer 22 described with reference to FIGS. 1A and 1B. In some embodiments, the substrate is a layer overlying the semiconductor substrate, such as a dielectric layer, a metal layer, a hard mask layer, or other suitable layer. In some embodiments, the mask layer is deposited by spin coating or other suitable process. The wafer having the mask layer formed in operation 540 thereon may be referred to as a “test wafer” or “inspection wafer.” The test wafer may be similar in many respects to a production wafer. In some embodiments, the test wafer is different from the production wafer, for example, in one or more physical characteristics.

In operation 550, defocused light is formed by shifting the mask assembly, the one or more optical path elements, or a combination thereof. The shifting may include shifting position, shifting rotation, or both. The shifting may be performed in the manner described with reference to FIGS. 4A-4D. The shifting may result in the incident light 480 having the focal plane 422 or 424 that coincides with the pellicle 370, the inner particle 350I, or a position near the inner particle 350I between the inner particle 350I and the reticle 218.

In operation 560, one or more images are taken of a region at or near the pellicle 370 by defocused light. The defocused light includes the incident light 480 having the focal plane 422 or 424. The image taking may include exposing the mask layer to the light 490 carrying information of the pellicle 370 and the inner particles 350I (when present), and patterning the mask layer based on the pattern. The image taking may further include etching a layer underlying the patterned mask layer to form openings, forming features in the openings, or both. The image taking may include exposing an image sensor of an EUV camera or EUV wavefront camera to the light 490 carrying the information of the pellicle 370 and the inner particles 350I (when present). In some embodiments, a single image is taken at a single focal plane, such as the focal plane 422. In some embodiments, two or more images are taken at a respective two or more focal planes, such as focal planes at the distances D6 described with reference to FIGS. 4A-4D.

In operation 570, the image(s) are analyzed to determine presence of one or more inner particles 350I on the inner surface of the pellicle 370. The image(s) may be analyzed using image processing techniques, such as edge detection, filtering, sharpening, smoothing, and the like. The image(s) may be analyzed by a wafer inspection tool, which may be an optical inspection tool. In some embodiments, the image(s) may be analyzed by a computing device including memory storing instructions for performing the analysis, and a processor that is configured to execute the instructions to analyze the image(s).

In some embodiments, analyzing the image(s) includes storing the image(s) in a database, storing analysis information of the image(s), or both. Based on the stored images and/or analysis information, the method 501 may trace the evolution of inner particles 350I, count the number of inner particles 350I, and establish a threshold value for triggering pellicle remounting proactively with reduced impact to fabrication of production wafers. Wafer yield can thereby be improved.

Tracing evolution of inner particles 350I may include determining change over time of one or more parameters of the inner particles 350I. For example, type and/or material composition of the inner particles 350I may be performed by analyzing the pellicle 370 having the inner particle(s) 350I thereon. For example, size of the inner particles 350I and change thereof over time (e.g., particles are decreasing in size over time) may be determined. Change in rate of inner particle accumulation over time may be determined. The above parameters may be analyzed for correlation with wafer yield, and a threshold value for triggering pellicle remounting may be established. For example, wafer yield may be reduced by a selected amount when number of the inner particles 350I is over a threshold value (e.g., 2, 5, 10, 100, or the like). For example, wafer yield may be reduced by a selected amount when size of the inner particles 350I exceeds a threshold value (e.g., 30 nm, 50 nm, 100 nm, or the like). The threshold value may be used in operation 580, as described following.

In operation 580, when an inner particle 350I is detected, the method 501 proceeds to operation 590. When no inner particle 350I is detected, the method 501 proceeds to operations 520 and 530 to perform processing of production wafers using focused light. In some embodiments, operation 580 proceeds to operation 590 when the threshold value is exceeded, and proceeds to operations 520 and 530 when the threshold value is not exceeded.

In operation 590, the pellicle 370 having one or more inner particles 350 thereon is replaced with a new pellicle. The replacing may include dismounting the frame 360 having the pellicle 370 thereon from the mask assembly 200, removing the pellicle 370 from the frame 360, inspecting the new pellicle for particles, attaching the new pellicle to the frame 360 when the new pellicle is substantially free or free of particles, and mounting the frame 360 including the new pellicle to the mask assembly 200. Following mounting the frame 360, the method may proceed to operation 540 to inspect the mounted new pellicle to ensure no inner particles 350I are present prior to performing production wafer processing. In some embodiments, the method may proceed directly to operation 530 without inspecting the mounted new pellicle for inner particles 350I.

In some embodiments, the incident light 480 has a first power when processing production wafers and a second power when detecting the inner particles 350I. The second power may be lower than the first power. Using a lower power may be advantageous to reduce wear on the light source 120 and save electricity.

Embodiments may provide advantages. The method 501 of the embodiments detects the inner particles 350I before the inner particles 350I settle on the mask pattern 230. The method 501 may trace the evolution of inner particles 350I, count the number of inner particles 350I, and establish a threshold value for triggering replacement of the pellicle 370 proactively with reduced impact to fabrication of production wafers. Wafer yield and throughput can thereby be improved.

In accordance with at least one embodiment, a method includes: determining whether a first pellicle is to be inspected for inner particles; and in response to the first pellicle being to be inspected: forming a mask layer on a substrate; forming a defocused light path by shifting a mask assembly; exposing the mask layer by defocused light having a focal plane separated from the first pellicle by a distance; taking an image of the substrate; determining whether a threshold value is exceeded by analyzing the image; in response to the threshold value being exceeded, replacing the first pellicle with a second pellicle; and in response to the threshold value not being exceeded, processing production wafers using the first pellicle.

In accordance with at least one embodiment, a method includes: mounting a first pellicle to a mask assembly; determining whether the first pellicle is to be inspected; and in response to the first pellicle being to be inspected: forming a defocused light path by shifting a reflector preceding the first pellicle; taking an image by defocused light having a focal plane between the first pellicle and a reticle of the mask assembly; determining whether an inner particle is present on the first pellicle by analyzing the image; in response to the inner particle being present: replacing the first pellicle with a second pellicle; and processing production wafers using the second pellicle; and in response to the inner particle not being present, processing production wafers using the first pellicle.

In accordance with at least one embodiment, a method includes: determining whether an inner particle is present on an inner surface of a first pellicle mounted on a reticle, the inner surface facing the reticle, the determining including directing defocused extreme ultraviolet (EUV) light toward the first pellicle, the defocused EUV light having a focal plane that is nearer to the first pellicle than to a mask pattern of the reticle; in response to the inner particle not being present, performing semiconductor processing on a production wafer by focused light with the first pellicle mounted to the reticle; and in response to the inner particle being present: removing the first pellicle; mounting a second pellicle to the reticle; and performing the semiconductor processing on the production wafer by the focused light with the second pellicle mounted to the reticle.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
determining whether a first pellicle is to be inspected for inner particles; and
in response to the first pellicle being to be inspected:
forming a mask layer on a substrate;
forming a defocused light path by shifting a mask assembly;
exposing the mask layer by defocused light having a focal plane separated from the first pellicle by a distance;
taking an image of the substrate;
determining whether a threshold value is exceeded by analyzing the image;
in response to the threshold value being exceeded, replacing the first pellicle with a second pellicle; and
in response to the threshold value not being exceeded, processing production wafers using the first pellicle.

2. The method of claim 1, wherein the forming a defocused light path includes shifting the mask assembly by a first distance associated with a second distance, the second distance being an offset distance from the first pellicle in a direction toward the mask assembly.

3. The method of claim 2, wherein the second distance is associated with a particle detection resolution of a wafer inspection tool.

4. The method of claim 2, wherein the second distance is based on a selected particle size associated with a pattern failure.

5. The method of claim 2, wherein the second distance is associated with an average size of historic inner particles.

6. The method of claim 1, wherein the determining whether a threshold value is exceeded includes determining whether a number of the inner particles present on the first pellicle exceeds a number threshold.

7. The method of claim 1, wherein the determining whether a threshold value is exceeded includes determining whether a size of at least one of the inner particles present on the first pellicle exceeds a size threshold.

8. A method, comprising:
mounting a first pellicle to a mask assembly;
determining whether the first pellicle is to be inspected; and
in response to the first pellicle being to be inspected:
forming a defocused light path by shifting a reflector preceding the first pellicle;
taking an image by defocused light having a focal plane between the first pellicle and a reticle of the mask assembly;
determining whether an inner particle is present on the first pellicle by analyzing the image;
in response to the inner particle being present:
replacing the first pellicle with a second pellicle; and
processing production wafers using the second pellicle; and
in response to the inner particle not being present, processing production wafers using the first pellicle.

9. The method of claim 8, further comprising:
mounting the second pellicle to the mask assembly; and
prior to the processing production wafers using the second pellicle:
taking a second image of the second pellicle by second defocused light having a second focal plane between the second pellicle and the reticle.

10. The method of claim 8, wherein the taking an image is by an extreme ultraviolet (EUV) camera.

11. The method of claim 10, wherein the extreme ultraviolet camera is an EUV wavefront camera.

12. The method of claim 8, wherein the forming a defocused light path is by further shifting a second reflector preceding the first pellicle.

13. The method of claim 8, wherein the shifting the first reflector includes moving a position of the first reflector.

14. The method of claim 13, wherein the shifting the first reflector further includes rotating an angle of the first reflector.

15. A method, comprising:
determining whether an inner particle is present on an inner surface of a first pellicle mounted on a reticle, the inner surface facing the reticle, the determining including directing defocused extreme ultraviolet (EUV) light toward the first pellicle, the defocused EUV light having a focal plane that is nearer to the first pellicle than to a mask pattern of the reticle;
in response to the inner particle not being present, performing semiconductor processing on a production wafer by focused light with the first pellicle mounted to the reticle; and
in response to the inner particle being present:
removing the first pellicle;
mounting a second pellicle to the reticle; and
performing the semiconductor processing on the production wafer by the focused light with the second pellicle mounted to the reticle.

16. The method of claim 15, wherein the defocused light has lower power than that of the focused light.

17. The method of claim 15, wherein the defocused light is formed by shifting position of the reticle.

18. The method of claim 17, wherein the reticle is shifted to a position at which the first pellicle lies on the focal plane of the defocused light.

19. The method of claim 17, wherein the determining further includes taking at least one image by a wavefront camera.

20. The method of claim 19, wherein the determining further includes calculating dynamics of image aberration using a defocus wavefront measurement of the wavefront camera.
